(19) United States
(12) Patent Application Publication
(10) Pub. No.: US 2025/0155826 A1
(43) Pub. Date: May 15, 2025

(54) PHOTOLITHOGRAPHY RETICLE STAGE DRIVE SYSTEM

(71) Applicant: Massachusetts Institute of Technology, Cambridge, MA (US)

(72) Inventors: Charles Byron Seaberg, Wimberley, TX (US); David L. Trumper, Plaistow, NH (US)

(73) Assignee: Massachusetts Institute of Technology, Cambridge, MA (US)

(21) Appl. No.: 18/941,077

(22) Filed: Nov. 8, 2024

Related U.S. Application Data
(60) Provisional application No. 63/597,409, filed on Nov. 9, 2023.

(51) Int. Cl. G03F 7/00

(52) U.S. Cl. CPC G03F 7/70725; G03F 7/70758; G03F 7/70766; G03F 7/70775; G03F 7/70875

(57) ABSTRACT

A reticle stage for a photolithography scanner is disclosed having a direct-drive ironless linear motor to actuate a short-stroke stage during a turnaround operation. The reticle stage may include a long stroke stage, an array of permanent magnets coupled to a beam, and at least one conductive coil mounted to the short-stroke stage without a ferromagnetic core. The beam may pass through the short-stroke stage and be coupled to one of the long-stroke stage or a balance mass, both of which may be disposed about the perimeter of the short-stroke stage. An electrical current applied to the coil may interact with the magnetic field from the permanent magnets to provide a force on the short-stroke stage.

### CROSS-REFERENCE TO RELATED APPLICATIONS

The present application claims priority to U.S. Provisional Patent Ser. No. 63/597,409, filed on Nov. 9, 2023, the content of which is hereby incorporated by reference in its entirety.

### STATEMENT REGARDING FEDERALLY SPONSORED RESEARCH

Not Applicable.

### FIELD OF TECHNOLOGY

The described technology generally relates to photolithography scanning tools, more particularly to an iron-less linear drive motor which enables high scan velocities and high acceleration turnaround trajectories.

### BACKGROUND

Photolithography is a step in the manufacturing of semiconductor chips. In photolithography, a photosensitive resist covering a silicon wafer is exposed to ultraviolet light in a design pattern which gives the chip its functionality. The pattern is created by modulating an exposure source with a reticle pattern such that the specified pattern of light is focused on the wafer. In modern photolithography scanners, only a slit of light is used to expose the wafer and the reticle and wafer are moved synchronously relative to the light source using actuators. Actuators must be capable of high forces to accelerate the reticle and wafer quickly, yet also maintain the precision required to adequately align the reticle and wafer during exposure.

Semiconductor photolithography requires the precise actuation of the reticle and wafer stages during the manufacture of integrated circuits. The wafer throughput of a scanning tool is bounded by the velocity and acceleration of the trajectories that the wafer and reticle follow. Maximizing tool throughput (i.e., minimizing manufacture time and maximizing the number of devices made) is an industry concern, given the widespread integration of semiconductors in commercial technologies and the potential of chip shortages. Additionally, reducing overall tool power consumption is important to reduce operating costs and meet sustainability objectives.

### SUMMARY

Aspects of the present disclosure relate to a reticle stage for a photolithography scanner having a direct-drive iron-less linear motor to actuate a short-stroke stage during a turnaround operation. The reticle stage may further include a long-stroke stage, an array of permanent magnets coupled to a beam, and at least one conductive coil mounted to the short-stroke stage. The beam may pass through the short-stroke stage and be coupled to one of the long-stroke stage or a balance mass, both of which may be disposed about the perimeter of the short-stroke stage.

According to one aspect, a reticle stage system may be configured to support a photolithography reticle. The reticle stage system may include a first stage defining a channel therethrough, a second stage disposed about the first stage and a beam extending through the channel of the first stage. An ironless drive motor may include one or more permanent magnets coupled to the beam. The one or more permanent magnets may form a magnetic field. At least one electrically conductive coil may be coupled to the first stage and disposed adjacent to the one or more permanent magnets. A controller may be coupled to the at least one electrically conductive coil and adapted to supply a current to the at least one electrically conductive coil to generate an electric field. An interaction between the electric field and the magnetic field may drive the first stage during a reticle turnaround operation.

The reticle stage system may further include, alone or in combination, one or more of the following features. The beam may be coupled to a balance mass. The beam may be coupled to the second stage. The at least one electrically conductive coil may comprise an aluminum coil. The at least one electrically conductive coil may be coupled to the first stage without a ferromagnetic core. At least a selection of the one or more permanent magnets may comprise a plurality of Halbach arrays. The plurality of Halbach arrays may comprise a first array and a second array disposed through the at least one electrically conductive coil and a third and fourth array oppositely disposed outside the at least one electrically conductive coil. The beam may comprise a first support and a second support. Each of the first support and second support may have a beam-facing surface. A first Halbach array may be disposed on the beam adjacent to the beam-facing surface of the first support. A second Halbach array may be disposed on the beam adjacent to the beam-facing surface of the second support. A third Halbach array may be disposed on the beam-facing surface of the first support. A fourth Halbach array may be disposed on the beam-facing surface of the second support. The second stage may comprise a second electrically conductive coil disposed adjacent to the one or more permanent magnets. The second electrically conductive coil may surround at least a portion of the beam. The at least one electrically conductive coil may include multiphase windings. The reticle stage system may comprise a heat-dissipation mechanism disposed adjacent to the first stage. The heat-dissipation mechanism may comprise a fluid supplied to the at least one electrically conductive coil. The heat-dissipation mechanism may comprise radiative cooling of a heat sink. The heat-dissipation mechanism may comprise a thermal capacitor. The thermal capacitor may use latent heat from phase change for cooling.

According to another aspect, a system may include a short-stroke stage defining a channel therethrough, a long-stroke stage disposed about the short-stroke stage and a beam extending through the channel of the short-stroke. An ironless drive motor may include one or more permanent magnets coupled to the beam, The one or more permanent magnets may form a magnetic field. At least one electrically conductive coil may surround at least a portion of the beam and may be coupled to the short-stroke stage. A controller may be coupled to the at least one electrically conductive coil and adapted to supply a current to the at least one electrically conductive coil to generate an electric field. An interaction between the electric field and the magnetic field may drive the first stage during a reticle turnaround operation.

The system may include, alone or in combination, one or more of the following features. A second electrically conductive coil may be coupled to the long-stroke stage and disposed surrounding a second portion of the beam. The one or more permanent magnets may include a plurality of Halbach arrays disposed adjacent to the beam. The plurality of Halbach arrays may comprise a first array and a second array disposed through the at least one electrically conductive coil, and a third and fourth array oppositely disposed outside the least one electrically conductive coil.

According to another aspect, a system may include a wafer stage configured to support a wafer during a photolithography operation and reticle actuation system configured to support a reticle. The reticle actuation system may include a first stage defining a channel therethrough, a second stage disposed about the first stage, and a beam extending through the channel of the first stage. An ironless drive motor may include one or more permanent magnets coupled to the beam. The one or more permanent magnets may form a magnetic field. At least one electrically conductive coil may be coupled to the first stage without a ferromagnetic core, and disposed adjacent to the one or more permanent magnets. A controller may be coupled to the at least one electrically conductive coil and adapted to supply a current to the at least one electrically conductive coil to generate an electric field. An interaction between the electric field and the magnetic field may drive the first stage during a reticle turnaround operation. An optical system including an illumination source and at least one optical element may be configured to optically couple a signal from the illumination source to the reticle actuation system and the wafer stage during the photolithography operation.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, aspects of the present disclosure are illustrated by way of example and not limitation in the figures, in which:

FIG. 1 is a block diagram of a photolithography scanner system, according to one aspect of the disclosure.

FIG. 2 is a top-down view of a reticle stage system with a linear drive motor, according to one aspect of the disclosure.

FIG. 3 is a sectional view of the linear drive motor of FIG. 2, take across line A-A, according to one aspect of the disclosure.

FIG. 4. is an isometric view of an electrically conductive coil, according to one aspect of the disclosure.

FIG. 5 is a top-down view of an alternative reticle stage system with a linear drive motor, according to one aspect of the disclosure.

FIG. 6 is a diagram of an example of a computing device, according to one or more aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

Modern photolithography scanners move a reticle to move along a scan axis at a constant velocity during exposure. The reticle moves back and forth repeatedly with this constant velocity, and during each scan, the pattern on the reticle may be transferred to the wafer in alternating directions.

Between scan exposures a turnaround operation is executed in which a large force is applied to the reticle stage with actuators. During turnaround, the wafer may be simultaneously repositioned to place a new field in the pathway for exposure. Minimization of reticle turnaround time may be desirable to increase machine throughput (e.g., wafers per hour). In order to improve turnaround operations, a direct-drive, iron-less linear motor may be implemented to actuate a short-stroke stage during the turnaround.

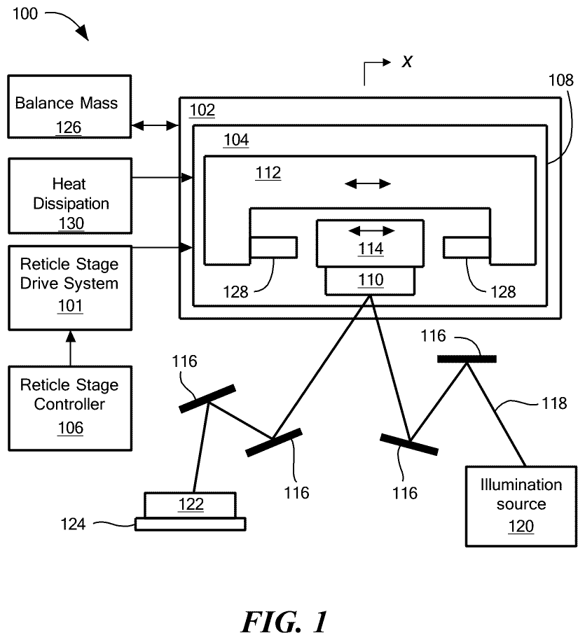

Referring now to FIG. 1, a photolithography system 100 may include a reticle actuation system 102 that may include a reticle stage drive system 101 coupled to a reticle stage 104. According to one aspect, the reticle stage drive system 101 may include a linear motor and may be used to magnetically levitate and move the reticle stage 104. Thus, the reticle actuation system 102 may operate such that in response to signals from a reticle stage controller 106, the reticle stage 104 may move during scan and turnaround operations.

Reticle stage 104 may be disposed in an enclosure 108. It should be noted that enclosure 108 may be coupled to a vacuum system (not explicitly shown in FIG. 1) capable of evacuating fluid (e.g., air) from enclosure 108. Thus, enclosure 108 may correspond to a vacuum chamber. It should also be appreciated that the reticle stage 104 may move within a vacuum environment. Furthermore, in the case where the photolithography system 100 is a next-generation photolithography system (e.g., an extreme ultraviolet (EUV) system) then the reticle stage 104 may move in an ultra-clean high-vacuum environment, as would be readily understood by one skilled in the art.

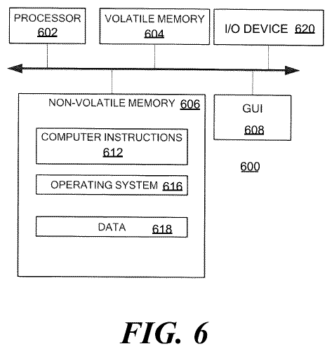

Reticle stage controller 106 may issue control signals or commands to control movement of the reticle stage 104. The reticle stage controller 106 may include, for example, control circuitry and software which provides signals to initiate movement (e.g., position reference signals profiles) of reticle stage 104 between one or more positions. The reticle stage controller may be, or may include, a computing device such as the computing device 600 described in connection with FIG. 6. The reticle stage controller 106 may also be capable of performing real-time control for motion and magnetic suspensions of the reticle stage 104. That is, the reticle stage controller 106 may include an active control capability, which may read sensor signals and send controlling commands to drive the actuators and drive motors for the reticle stage 104, as described herein. According to one aspect, a heat-dissipation mechanism 130 may be employed to extract the heat and cool the system and its components. The heat dissipation mechanism 130 may also be coupled to the reticle stage controller and configured to extract heat generated by, for example, a linear drive motor, as described herein.

The reticle stage 104 may include a long-stroke stage 112 and short-stroke stage 114, to which a reticle 110 is clamped. The long-stroke stage 112 may have a larger travel and follow the reticle trajectory within several micrometers. The short-stroke stage 114 may be restricted to remain within about +0.5 millimeters (mm) of the long-stroke stage 112 but is intended to follow the reticle trajectory with sub-nanometer error. According to one aspect, to achieve the required accuracy and precision, the short-stroke stage 114 may be magnetically levitated and controlled in six degrees-of-freedom (DOF) using scan actuators (not shown) mounted to the long-stroke stage 112 with corresponding components on the short-stroke stage 114.

The reticle stage drive system 101 of the reticle actuation system 102 may be capable of moving the reticle 110 during scan and turnaround operations. According to one aspect of the disclosure, one or more actuators 128 may be mounted to the long-stroke stage 112 and may be driven by the reticle stage drive system 101 to position the short-stroke stage 114 during a scanning operation. During turnaround, described in greater detail below, a linear motor with a moving coil mounted to the short-stroke stage 114 may be used to provide force in the scan direction to move the short-stroke stage 114.

In operation, the reticle 110 may be disposed in a vacuum chamber which contains optical elements 116 which may reflect or otherwise direct a signal 118 (e.g., a light or laser signal) from an illumination source 120 toward a substrate, such as a wafer 122. The wafer 122 may be disposed on a moveable wafer stage 124. During a scan operation, the illumination source 120 may transmit the signal 118 through the optical elements 116, through the reticle 110 so as to produce a desired pattern on the wafer 122. It should be appreciated that not all of the elements in the photolithography system 100 are shown in FIG. 1. For simplicity and to promote clarity in FIG. 1, some conventional components necessary to use and direct light to transfer a desired geometric pattern from the reticle to a substrate have not been shown in FIG. 1, however such elements and their functionality would be well-understood by a person skilled in the art.)

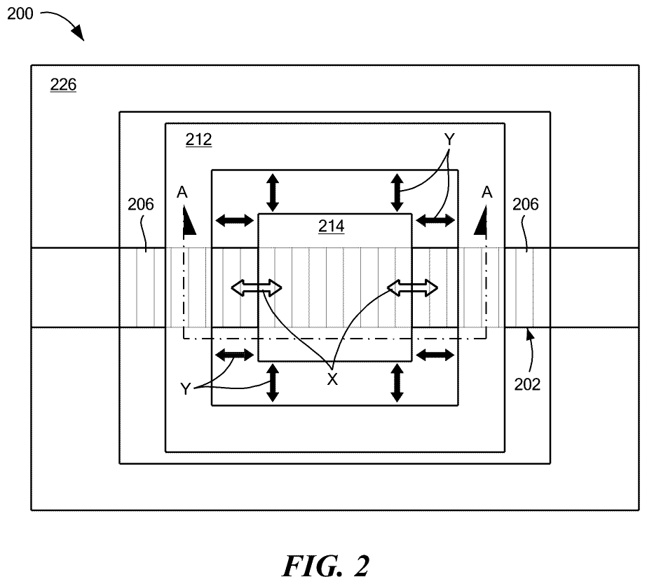

The reticle stage 104 may react against a balance mass 126 to avoid transmission of reaction forces into the frame of the photolithography system 100 when the reticle stage 104 is accelerating. While the balance mass 126 is shown in FIG. 1 apart from the reticle stage, one skilled in the art will recognize that the balance mass 126 may be integrated with the reticle stage 104, particularly as explained herein and shown in FIGS. 2-5.

While the photolithography system 100 and its exemplary optics depicted in FIG. 1 may be configured for extreme ultraviolet lithography (EUV), one skilled in the art will recognize that the concepts, systems, and methods described herein may also be implemented in a deep ultraviolet (DUV) tool without deviating from the scope of the present disclosure.

Referring now to FIGS. 2-4, a reticle stage system 200 including a linear drive motor is shown, according to one aspect of the disclosure. FIG. 2 is a top-down view of a portion of the reticle stage system 200. A balance mass 226 may be disposed about the perimeter of a long-stroke stage 212. The long-stroke stage 212 may be disposed about the perimeter of a short-stroke stage 214. Each of the long-stroke stage 212 and the short-stroke stage 214 may include or define a channel extending from one side to the opposing side through their respective bodies. According to one aspect, the balance mass 226 may include a beam 202 extending across its width and passing through the long-stroke stage 212 and short-stroke stage 214, for example through the channels defined in each body. The short-stroke stage 214 may include one or more scan actuators with corresponding components on the long-stroke stage 212 (not explicitly shown in FIGS. 2-4) configured to drive (e.g., actuate) the short-stroke stage on multiple axes of movement (shown by the arrows Y).

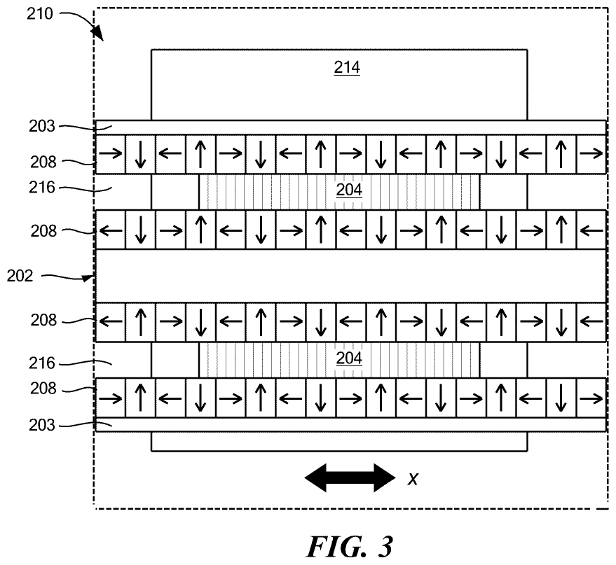

According to one aspect, the reticle stage 200 may further include an iron-less linear drive motor 210 (FIG. 3) to provide force to (e.g. drive) the short-stroke stage 214 in a scanning direction (shown by arrows X) during reticle stage turnaround operations. FIG. 3 is a partial cross-sectional view, taken across line A-A of FIG. 2, of the iron-less linear drive motor 210 according to one aspect. The drive motor 210 may include one or more moving coils 204 coupled to the short-stroke stage 214. The one or more moving coils 204 may be formed from or include electrically conductive material.

According to one aspect, a track of permanent magnets 206 (FIG. 2) may be coupled to the beam 202 of the balance mass 226 and configured to interact with the coil 204 to absorb motor reaction forces. According to one aspect, the beam 202 may include one or more supports 203 (FIG. 3) disposed adjacent to and extending along opposing surfaces of the beam 202. These supports 203 may not only support the permanent magnet track 206, but also guide the magnetic flux if made of a ferromagnetic material. The beam 202 and supports 203 may include or define one or more air gaps 216 between the respective facing surfaces of the beam 202 and the supports 203. According to one aspect, each of the supports 203 may include beam-facing surfaces adapted to support at least a portion of the permanent magnets 206.

According to one aspect the permanent magnets 206 may include one or more Halbach arrays. Halbach arrays may include a number of permanent magnets arranged to augment the magnetic field on one side of the array while reducing the magnetic field on the other side to near zero. In the example drive motor 210 of FIG. 3, four Halbach arrays 208 may be implemented. According to one aspect, the Halbach arrays 208 may be used to create a magnetic field (indicated by the directional arrows of each magnet 206) in the air gaps 216 through which the coil 204 passes.

Electrical current supplied to the coil 204 may result in a driving force of the short-stroke stage 214, coupled to the coil 204, in the scan direction, x, due to the Lorentz force. That is, as electrical current passes through the coil 204, the interaction with the magnetic field from the Halbach arrays 208 will drive the movement of the short-stroke stage 214 in the scan direction. In order to efficiently generate force throughout the length of travel, coil windings 204 may need multiple phases and proper commutation based on the magnet array configuration and displacement of the mover relative to the stator. According to one aspect, extended magnet tracks mounted to the opposing surfaces of the beam 202 (e.g., top and bottom surfaces) and to the beam-facing surfaces of the supports 203 may be implemented such that force can be generated throughout the entire length of scan and turnaround operations. Since the permanent magnets 206 are coupled to the balance mass 226, the added magnet mass of the arrays 208 is not detrimental to stage efficiency. According to one aspect, the linear motor of the long-stroke stage 212 (i.e., the motor to drive the long-stroke stage 212 in scanning and turnaround operations) may also utilize a moving-coil linear motor to leverage the presence of the magnets 206 on the balance mass 226 and generate actuation forces.

According to one aspect, the Lorentz force for a conductor of volume V with uniform current density \vec{J} in a uniform magnetic B-field \vec{B} may be given as:

$$\vec{F} = ( \vec{J} \times \vec{B} ) V \qquad ( 1 )$$

According to one aspect, a magnetic design may be implemented in which the average magnitude of the vertical component of the field in the air gap 216 is about 0.5 Tesla (T) and a coil current density of about 10 amperes per square millimeter (A/mm²). As such, a coil 204 with a volume of about 2×10⁻³ cubic meters (m³) may be required to achieve about 10 kilonewtons (kN) of force on the short-stroke stage 214. If the coil 204 is formed from aluminum instead of copper (e.g., for decreased mass density), then the mass of the coil 204 required for an acceleration of about 100 g acceleration may be about 5.4 kilograms (kg).

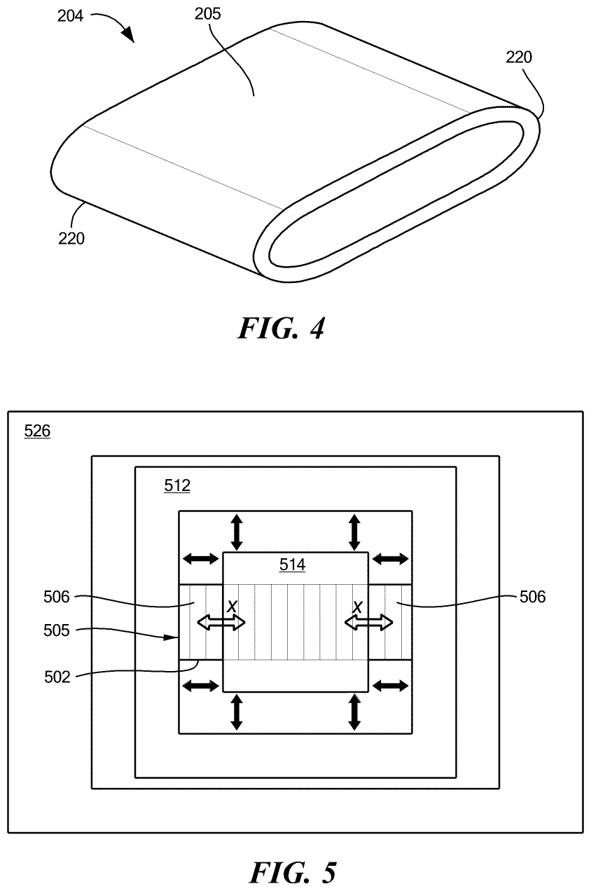

FIG. 4 is an isometric view of a shaped coil 204 capable of creating the exemplary conductor volume, according to one aspect. The coil 204 may have a substantially square active area 205 of a top or bottom surface, for example, 315 mm×315 mm, and a coil thickness of about 10 mm. According to one aspect, the coil 204 may include multiphase windings with proper commutation to match a spatial variation of the magnetic field produced by the Halbach arrays 208. One skilled in the art will appreciate the above analysis may be simplified to use an average magnetic field and coil sizing for initial sizing based on simplified physics, however a skilled artisan will further recognize that other applied fields and coil sizes may be implemented without deviating from the scope of the disclosure.

According to one aspect, the joule losses in the coil 204, P, may be calculated using the resistivity, ρ, of the coil as:

$$P = ρ {J}^{2} V \qquad ( 2 )$$

If an aluminum resistivity of ρ=2.65×10⁻⁸ ohm-meters (Ωm) is assumed, then the power loss in the active motor area may be about 5.3 kilowatts (kW). One skilled in the art will appreciate the estimates for the weight and power loss of the coil 204 may be for the active area 205 and real values may be larger due to unused conductor geometry at the end turns 220 of the coil 204.

According to one aspect, because the linear drive motor 210 may only be used during turnaround, the duty cycle, d, of the motor may be given as:

$$d = \frac{{t}_{turnaround}}{{t}_{turnaround} + {t}_{scan}} \qquad ( 3 )$$

in which t_{turnaround} is the duration of a turnaround operation and t_{scan} is the duration of a scan operation. Using exemplary values of a scan velocity of 8 meters per second (m/s), scan length of 170 mm, and turnaround acceleration of 1000 meters per second squared (m/s²), the duty cycle may be d=43%. Accordingly, the average joule losses in the coil throughout operation may be:

$${P}_{avg} = dP = 2.3 kW \qquad ( 4 )$$

A linear drive motor may generate significant heat. According to one aspect, a heat-dissipation mechanism may be employed to extract the heat and cool the coil 204 with a fluid. The fluid may be supplied or provided to the short-stroke stage 214 to interact locally with the coil 204. The fluid may be brought, for example by one or more hoses, onto the short-stroke stage 214 to interact locally with the coil 204. In embodiments in which a hose or other structure are used to supply the fluid, special attention may be made to limit the disturbance forces caused by such a hose or other structure supplying the cooling fluid to maintain scan accuracy of the sub-nanometer short-stroke stage 214. This may be accomplished, according to one aspect, by active actuation. For example, in the case of a hose, an actively-controlled cable feed may be used to position the hose to minimize disturbance forces on the short-stroke stage. Alternatively, cooling methods may also or instead include radiative cooling of a high temperature heat sink, or the use of a thermal capacitor to cool coils 204 during steady-state oscillation. Such a capacitor may be recharged at a point when contact with the short-stroke stage 214 occurs. To gain high cooling energy densities, a phase change material utilizing latent heat may be used in the thermal capacitor.

According to one aspect of the disclosure, the disturbance forces during the constant velocity scan portion of the trajectory may be minimized. As mentioned herein, sub-nanometer level positional error may be required of the short-stroke stage 214 during a turnaround operation. According to one aspect, the linear drive motor 210 may be ironless, meaning that, as used herein, conductive coils attached to the short-stroke stage 214 are not wound on a ferromagnetic core (e.g. iron). Often, ferromagnetic material is used in the form of teeth or slots to guide magnetic flux and increase motor shear stress. Note that, according to aspects of the present disclosure, ferromagnetic material may still be used on the magnet-side of the linear motor in the form of a back iron. As such, the linear drive motor 210 may not experience disturbance forces such as cogging that may be present in linear motors with iron cores. Furthermore, the linear drive motor 210 may not experience disturbance forces due to hysteresis in a ferromagnetic core. Additionally, since the linear driver motor 210 may be turned off during scan operations, force ripple due to the interaction of driven coil phases with the magnet harmonics may not occur. However, due to the large relative velocity between the coil 204 and the Halbach arrays 208, eddy currents may be induced in the aluminum windings of the coil 204, despite the windings being open-circuited, and cause a disturbance force during scan.

FIG. 5 shows a top-down view of an alternative configuration of a reticle stage [[500 implemented to reduce eddy currents in the windings of an electrically conductive coil, according to one aspect of the disclosure. A magnet stator 505 (including permanent magnets 506) may be mounted to a beam 502 extending across the long-stroke stage 512, rather than the balance mass 526 as previously described. The coupling of the magnet stator 505 to the long-stroke stage 512 may result in a lower relative velocity between the coil (not shown), coupled to the short-stroke stage 514, and permanent magnets 506. Accordingly, the back-electromagnetic fields (EMF) the coil may experience may be decreased. As a trade-off, however, the mass of the permanent magnets 506 may now be carried by the long-stroke stage 512 and the beam 502.

Referring to FIG. 6, in some embodiments, a computing device 600, such as a controller, driver, or the like, may include processor 602, volatile memory 604 (e.g., RAM), non-volatile memory 606 (e.g., a hard disk drive, a solid-state drive such as a flash drive, a hybrid magnetic and solid-state drive, etc.), graphical user interface (GUI) 608 (e.g., a touchscreen, a display, and so forth) and input/output (I/O) device 620 (e.g., a mouse, a keyboard, etc.). Non-volatile memory 606 stores computer instructions 612, an operating system 916 and data 618 such that, for example, the computer instructions 612 are executed by the processor 602 out of volatile memory 604. Program code may be applied to data entered using an input device of GUI 608 or received from I/O device 620.

According to one aspect of the disclosure, the linear drive motors described herein may be compatible with the reflective reticles used in EUV tools. To accommodate transmissive optics found in DUV tools, however, the linear drive motor may be split into two separate motors and two magnet tracks positioned symmetrically above and below the reticle. Splitting the motor into two parts may be required to avoid actuator forces creating a moment about the short-stroke stage's center of mass.

Based on the teachings, one skilled in the art should appreciate that the scope of the present disclosure is intended to cover any aspect of the present disclosure, whether implemented independently of or combined with any other aspect of the present disclosure. For example, an apparatus may be implemented or a method may be practiced using any number of the aspects set forth. In addition, the scope of the present disclosure is intended to cover such an apparatus or method practiced using other structure, functionality, or structure and functionality in addition to, or other than the various aspects of the present disclosure set forth. It should be understood that any aspect of the present disclosure may be embodied by one or more elements of a claim.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within +10% of making a 90° angle with the second direction in some embodiments, within ±5% of making a 90° angle with the second direction in some embodiments, and yet within ±2% of making a 90° angle with the second direction in some embodiments.

As used herein, the term “determining” encompasses a wide variety of actions. For example, “determining” may include calculating, computing, processing, deriving, investigating, looking up (e.g., looking up in a table, a database or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

The various illustrative logical blocks, modules and circuits described in connection with the present disclosure may be implemented or performed with a processor specially configured to perform the functions discussed in the present disclosure. The processor may be a neural network processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. Alternatively, the processing system may comprise one or more neuromorphic processors for implementing the neuron models and models of neural systems described herein. The processor may be a microprocessor, controller, microcontroller, or state machine specially configured as described herein. A processor may also be implemented as a combination of computing devices, e.g., a combination of a DSP and a microprocessor, a plurality of microprocessors, one or more microprocessors in conjunction with a DSP core, or such other special configuration, as described herein.

The steps of a method or algorithm described in connection with the present disclosure may be embodied directly in hardware, in a software module executed by a processor, or in a combination of the two. A software module may reside in storage or machine readable medium, including random access memory (RAM), read only memory (ROM), flash memory, erasable programmable read-only memory (EPROM), electrically erasable programmable read-only memory (EEPROM), registers, a hard disk, a removable disk, a CD-ROM or other optical disk storage, magnetic disk storage or other magnetic storage devices, or any other medium that can be used to carry or store desired program code in the form of instructions or data structures and that can be accessed by a computing system. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and processing, including the execution of software stored on the machine-readable media. Software shall be construed to mean instructions, data, or any combination thereof, whether referred to as software, firmware, middleware, microcode, hardware description language, or otherwise.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or specialized register files. Although the various components discussed may be described as having a specific location, such as a local component, they may also be configured in various ways, such as certain components being configured as part of a distributed computing system.

The machine-readable media may comprise a number of software modules. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a special purpose register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any storage medium that facilitates transfer of a computer program from one place to another.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means, such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A reticle stage system configured to support a photolithography reticle, the reticle stage system comprising:
a first stage defining a channel therethrough;
a second stage disposed about the first stage;
a beam extending through the channel of the first stage;
an ironless drive motor comprising:
one or more permanent magnets coupled to the beam, the one or more permanent magnets forming a magnetic field;
at least one electrically conductive coil coupled to the first stage and disposed adjacent to the one or more permanent magnets; and
a controller coupled to the at least one electrically conductive coil and adapted to supply a current to the at least one electrically conductive coil to generate an electric field, wherein an interaction between the electric field and the magnetic field drives the first stage during a reticle turnaround operation.

2. The reticle stage system of claim 1, wherein the beam is coupled to a balance mass.

3. The reticle stage system of claim 1 wherein the beam is coupled to the second stage.

4. The reticle stage system of claim 1 wherein the at least one electrically conductive coil comprises an aluminum coil.

5. The reticle stage system of claim 1 wherein the at least one electrically conductive coil is coupled to the first stage without a ferromagnetic core.

6. The reticle stage system of claim 1 wherein at least a selection of the one or more permanent magnets comprise a plurality of Halbach arrays.

7. The reticle stage system of claim 6 wherein the plurality of Halbach arrays comprises a first array and a second array disposed through the at least one electrically conductive coil, and a third and fourth array oppositely disposed outside the at least one of the at least one electrically conductive coil.

8. The reticle stage system of claim 7 wherein:
the beam comprises a first support a second support, each of the first support and second support having a beam-facing surface;
a first Halbach array disposed on the beam adjacent to the beam-facing surface of the first support;
a second Halbach array disposed on the beam adjacent to the beam-facing surface of the second support;
a third Halbach array disposed on the beam-facing surface of the first support; and
a fourth Halbach array disposed on the beam-facing surface of the second support.

9. The reticle stage system of claim 1 wherein the second stage comprises a second electrically conductive coil disposed adjacent to the one or more permanent magnets.

10. The reticle stage system of claim 1 wherein the at least one electrically conductive coil includes multiphase windings.

11. The reticle stage system of claim 1 further comprising a heat-dissipation mechanism disposed adjacent to the first stage.

12. The reticle stage system of claim 11 wherein the heat-dissipation mechanism comprises a fluid supplied to the at least one electrically conductive coil.

13. The reticle stage system of claim 11 wherein the heat-dissipation mechanism comprises radiative cooling of a heat sink.

14. The reticle stage system of claim 11 wherein the heat-dissipation mechanism comprises a thermal capacitor.

15. The reticle stage system of claim 14 wherein the thermal capacitor uses latent heat from phase change for cooling.

16. A system comprising:
a short-stroke stage defining a channel therethrough;
a long-stroke stage disposed about the short-stroke stage;
a beam extending through the channel of the short-stroke stage;
an ironless drive motor comprising:
one or more permanent magnets coupled to the beam, the one or more permanent magnets forming a magnetic field;
at least one electrically conductive coil surrounding at least a portion of the beam and coupled to the short-stroke stage; and
a controller coupled to the at least one electrically conductive coil and adapted to supply a current to the at least one electrically conductive coil to generate an electric field, wherein an interaction between the electric field and the magnetic field drives the short-stroke stage during a reticle turnaround operation.

17. The system of claim 16 further comprising a second electrically conductive coil coupled to the long-stroke stage and disposed surrounding a second portion of the beam.

18. The system of claim 16 wherein the one or more permanent magnets includes a plurality of Halbach arrays disposed adjacent to the beam.

19. The system of claim 18 wherein the plurality of Halbach arrays comprise a first array and a second array disposed through the at least one electrically conductive coil, and a third and fourth array oppositely disposed outside the at least one electrically conductive coil.

20. A system comprising:
a wafer stage configured to support a wafer during a photolithography operation;
a reticle actuation system configured to support a reticle, the reticle actuation system including;
a first stage defining a channel therethrough;
a second stage disposed about the first stage;
a beam extending through the channel of the first stage;
an ironless drive motor comprising:
one or more permanent magnets coupled to the beam, the one or more permanent magnets forming a magnetic field;
at least one electrically conductive coil coupled to the first stage without a ferromagnetic core, and disposed adjacent to the one or more permanent magnets; and
a controller coupled to the at least one electrically conductive coil and adapted to supply a current to the at least one electrically conductive coil to generate an electric field, wherein an interaction between the electric field and the magnetic field drives the first stage during a reticle turnaround operation; and
an optical system including an illumination source and at least one optical element configured to optically couple a signal from the illumination source to the reticle actuation system and the wafer stage during the photolithography operation.
